(19) United States
(12) Patent Application Publication
(10) Pub. No.: US 2015/0296637 A1
(43) Pub. Date: Oct. 15, 2015

(54) CASING STRUCTURE FOR SERVER

(71) Applicant: WEI-MEI SHIH, Chiayi City (TW)

(72) Inventor: WEI-MEI SHIH, Chiayi City (TW)

(21) Appl. No.: 14/340,562

(22) Filed: Jul. 25, 2014

(30) Foreign Application Priority Data
Apr. 11, 2014 (TW) 103206327

(51) Int. Cl. H05K 5/00; H02K 7/116; H02K 5/22; H05K 5/02

(52) U.S. Cl. CPC H05K 5/0082; H05K 5/0239; H02K 7/116; H02K 5/22

(57) ABSTRACT

A casing structure for a server contains: a casing assembly including includes a driving assembly and a transmission assembly. The driving assembly includes a body, a motor, a drive, and a cover, wherein one end of the motor extends out of the body and connects with a first gear. The body includes a retaining portion having four orifices. The transmission assembly includes a case and a cap having a reduction gear set, and the reduction gear set includes a second gear and a third gear, the case has four third apertures and two opposite fourth apertures, the cap also includes an outer face for fixing a toothed output post, four first openings, and two opposite second openings. The case also has a groove defined on an outer side thereof to correspond to the retaining portion of the driving assembly and a first aperture for corresponding to the first gear.

### FIELD OF THE INVENTION

The present invention relates to a casing structure for a server which replaces the transmission assembly quickly.

### BACKGROUND OF THE INVENTION

With reference to FIG. 5, a conventional server contains: a casing 91, a reduction gear set 92, a motor, and a drive IC (not shown). The motor 93 and the drive IC are mounted in the casing 91, and the reduction gear set 92 is fixed outsides the casing 91 which is covered by a cover 94. The drive IC controls the motor 93 to rotate, and the reduction gear 92 is driven to rotate by the motor 93 so that the driver is applicable for a remote mechanism. However, when one of plural gears of the reduction gear set 92 is broken, the reduction gear set 92 has to be removed from the server, thus casing troublesome replacement.

The present invention has arisen to mitigate and/or obviate the afore-described disadvantages.

### SUMMARY OF THE INVENTION

The primary objective of the present invention is to provide a casing structure for a server which replaces the transmission assembly quickly.

To obtain the above objectives, a casing structure for a server provided by the present invention contain: a casing assembly, and the casing assembly includes a driving assembly and a transmission assembly.

The driving assembly includes a body in which a motor and a drive are mounted, and the driving assembly also includes a cover for covering the body, one end of the motor extends out of the body and connects with a first gear, the body includes a retaining portion arranged on one side thereof, and the retaining portion has four orifices defined on four corners thereof.

The transmission assembly includes a case and a cap covered the case, wherein the case has a reduction gear set accommodated therein, the reduction gear set at least includes a second gear located at a starting end thereof and a third gear located on an output end thereof, the case has four third apertures arranged on four corners thereof and two opposite fourth apertures formed on two sides of a middle section thereof, the cap includes an outer face for fixing a toothed output post of the third gear, four first openings defined on four corners thereof to insert though four first screw bolts, and two opposite second openings arranged on two sides of a middle section thereof to insert through two second screw bolts, such that the two second screw bolts are screwed with the two opposite fourth apertures via the two opposite second openings, and the case is connected with the cap.

The case also has a groove defined on an outer side thereof to correspond to the retaining portion of the driving assembly, and a first aperture for corresponding to the first gear.

### BRIEF DESCRIPTION OF THE DRAWINGS

FIG. 1 is a perspective view showing the exploded components of a casing structure for a server according to a preferred embodiment of the present invention.

FIG. 2 is another perspective view showing the exploded components of the casing structure for the server according to the preferred embodiment of the present invention.

FIG. 3 is a perspective view showing the assembly of the casing structure for the server according to the preferred embodiment of the present invention.

FIG. 4 is a plane view showing two ends of the driving assembly electrically connecting with two signal coupling portions according to the preferred embodiment of the present invention.

FIG. 5 is a perspective view of a conventional server.

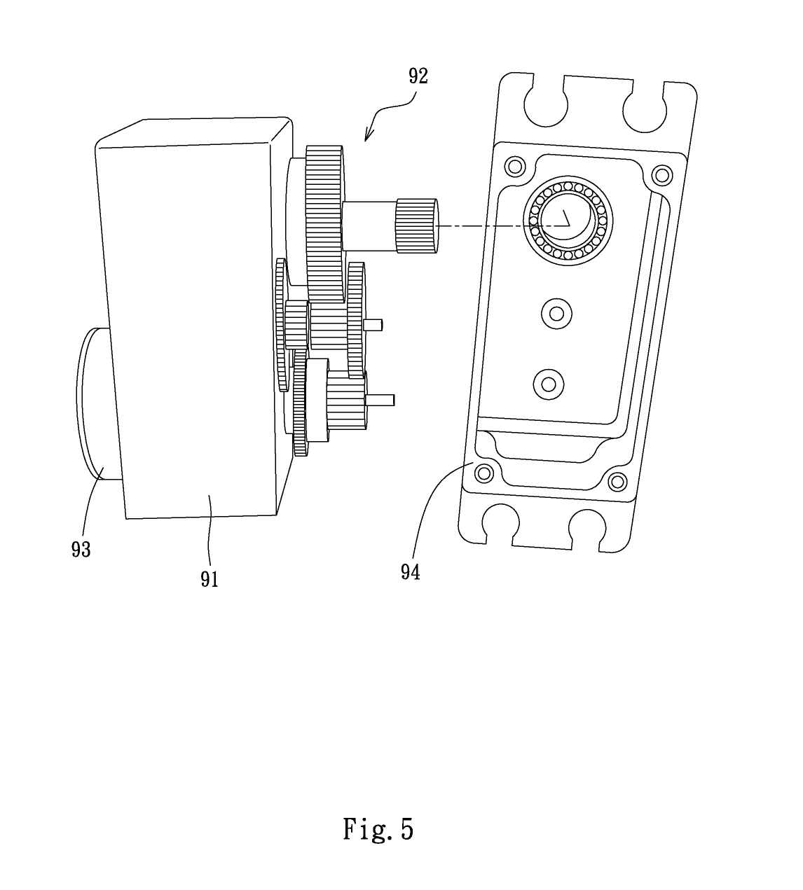

### DETAILED DESCRIPTION OF THE PREFERRED EMBODIMENTS

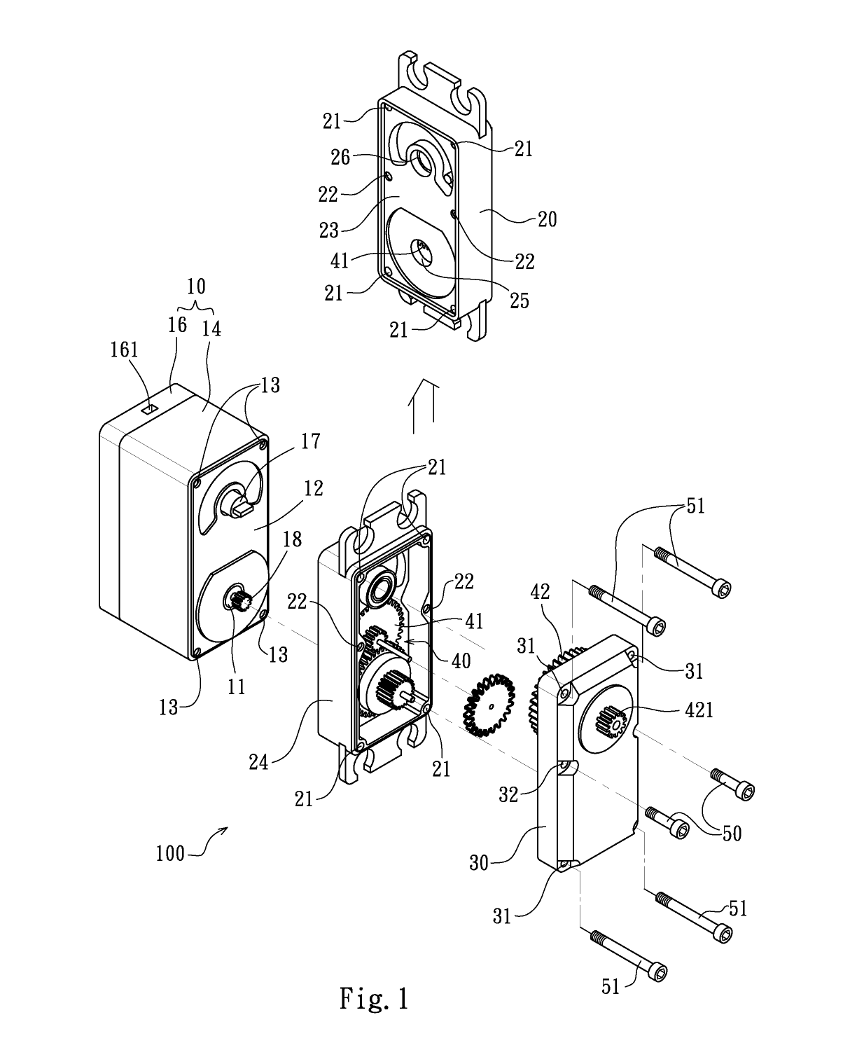

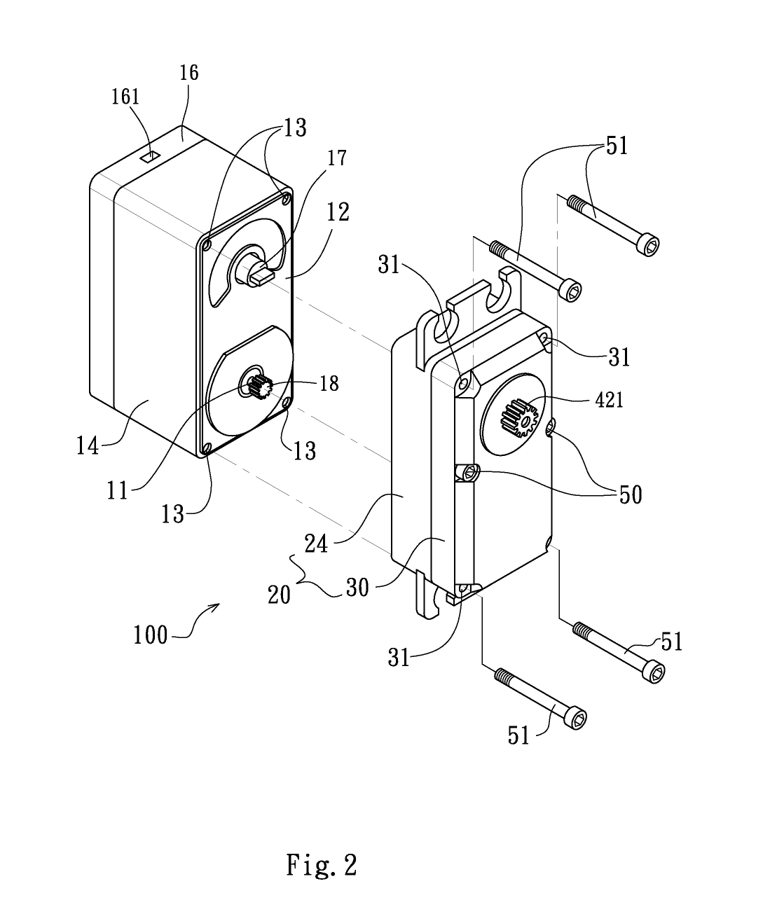

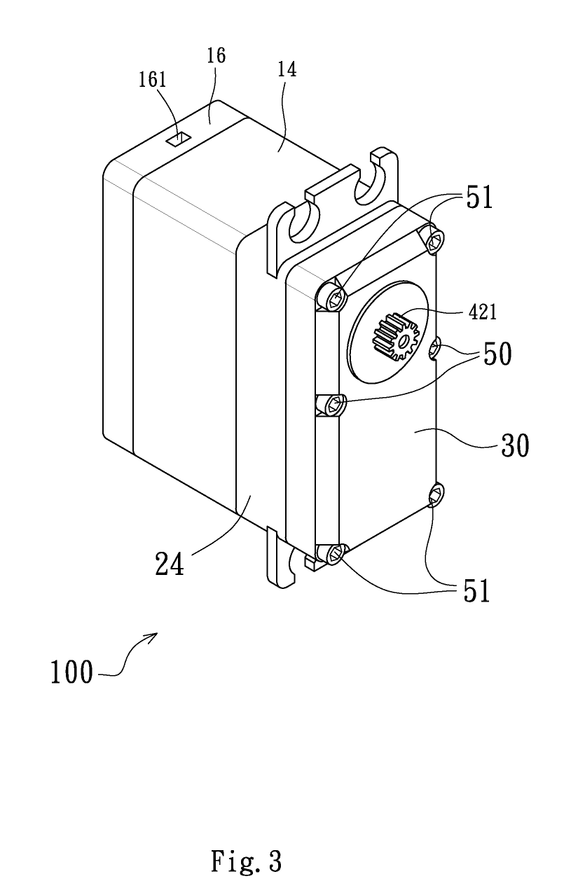

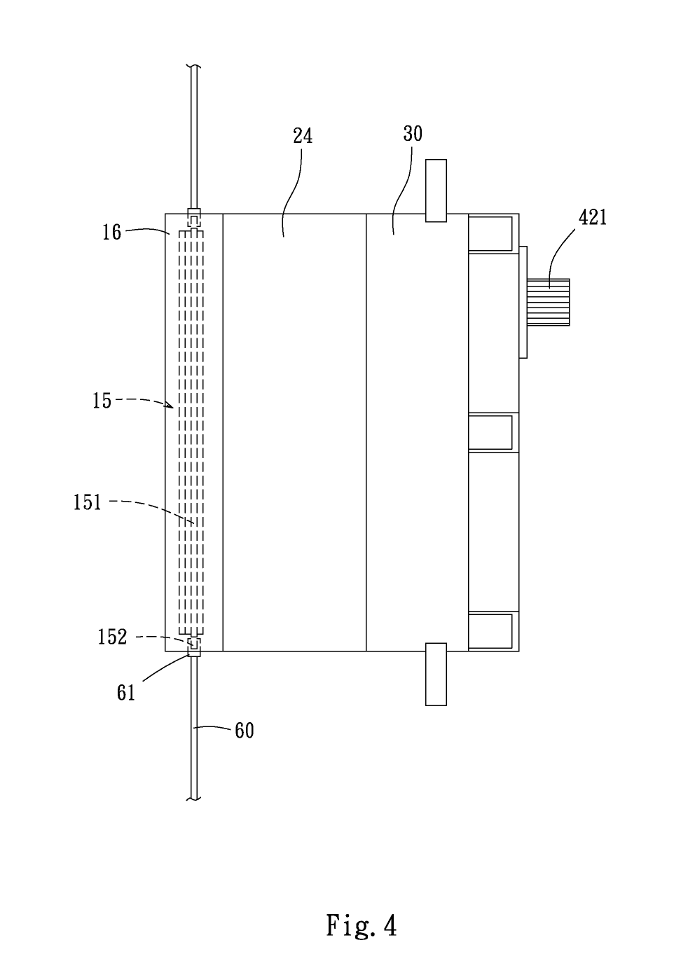

With reference to FIGS. 1 to 4, a casing structure for a server according to a preferred embodiment of the present invention comprises: a casing assembly 100, and the casing assembly 100 includes a driving assembly 10 and a transmission assembly 20. The driving assembly 10 includes a body 14 in which a motor 11, a drive IC 15, and a sensing shaft 17 for sensing a rotating angle of at least one gear are mounted. The driving assembly 10 also includes a cover 16 for covering the body 14. The body 14 includes a retaining portion 12 arranged on one side thereof, and the retaining portion 12 has four orifices 13 defined on four corners thereof. The drive IC 15 at least has a circuit board 151 and two signal coupling portions 152 extending outwardly from two ends of the circuit board 151. The cover 16 has two holes 161 formed on two ends thereof and corresponding to the two signal coupling portions 152, such that of two plugs 61 of two signal cables 60 are inserted into the two holes 161 to electrically connect with the two signal coupling portions 152. In addition, one end of the motor 11 extends out of the body 14 and connects with a first gear 18, and one end of the sensing shaft 17 extends out of the body 14 as well.

The transmission assembly 20 includes a case 24 and a cap 30 covered the case 24, wherein the case 24 has a reduction gear set 40 accommodated therein, a groove 23 defined on an outer side thereof to correspond to the retaining portion 12 of the driving assembly 10, a first aperture 25 for corresponding to the first gear 18, a second aperture 26 for corresponding to the sensing shaft 17, four third apertures 21 arranged on four corners of the case 24, and two opposite fourth apertures 22 formed on two sides of a middle section of the case 24.

The reduction gear set 40 at least includes a second gear 41 located at a starting end thereof and a third gear 42 located on an output end thereof.

The cap 30 includes an outer face for fixing a toothed output post 421, four first openings 31 defined on four corners thereof to insert though four first screw bolts 51, and two opposite second openings 32 arranged on two sides of a middle section thereof to insert through two second screw bolts 50, such that the two second screw bolts 50 are screwed with the two opposite fourth apertures 22 via the two opposite second openings 32, and the case 24 is connected with the cap 30.

In assembly, the retaining portion 12 of the driving assembly 10 is retained in the groove 23 of the transmission assembly 20, the sensing shaft 17 is inserted into the case 24 through the second aperture 26 to connect with the third gear 42, and the first gear 18 is inserted through the first aperture 25 to mesh with the second gear 41. Furthermore, the four first screw bolts 51 are inserted into the four third apertures 21 of the transmission assembly 20 and the four first openings 31 of the cap 30 to screw with the four orifices 13 of the driving assembly 10, thus connecting the casing assembly 100.

Thereby, when the reduction gear set 40 is broken, the cap 30 is removed to replace the reduction gear set 40 or the transmission assembly 20 is removed to replace the transmission assembly 20, thereby replacing the transmission assembly 20 quickly. Moreover, the drive IC 15 has the two signal coupling portions 152 extending outwardly from two ends of the circuit board 151 so that two ends of the driving assembly 10 can electrically connect with the two signal coupling portions 152.

While the preferred embodiments of the invention have been set forth for the purpose of disclosure, modifications of the disclosed embodiments of the invention as well as other embodiments thereof may occur to those skilled in the art. Accordingly, the appended claims are intended to cover all embodiments which do not depart from the spirit and scope of the invention.

What is claimed is:

1. A casing structure for a server comprising: a casing assembly, and the casing assembly including a driving assembly and a transmission assembly, wherein
the driving assembly includes a body in which a motor and a drive are mounted, and the driving assembly also includes a cover for covering the body, one end of the motor extends out of the body and connects with a first gear, the body includes a retaining portion arranged on one side thereof, and the retaining portion has four orifices defined on four corners thereof;
the transmission assembly includes a case and a cap covered the case, wherein the case has a reduction gear set accommodated therein, the reduction gear set at least includes a second gear located at a starting end thereof and a third gear located on an output end thereof, the case has four third apertures arranged on four corners thereof and two opposite fourth apertures formed on two sides of a middle section thereof, the cap includes an outer face for fixing a toothed output post of the third gear, four first openings defined on four corners thereof to insert though four first screw bolts, and two opposite second openings arranged on two sides of a middle section thereof to insert through two second screw bolts, such that the two second screw bolts are screwed with the two opposite fourth apertures via the two opposite second openings, and the case is connected with the cap;
the case also has a groove defined on an outer side thereof to correspond to the retaining portion of the driving assembly, and a first aperture for corresponding to the first gear.

2. The casing structure for the server as claimed in claim 1, wherein the drive IC at least has a circuit board and two signal coupling portions extending outwardly from two ends of the circuit board, the cover has two holes formed on two ends thereof and corresponding to the two signal coupling portions, such that of two plugs of two signal cables are inserted into the two holes to electrically connect with the two signal coupling portions.

3. The casing structure for the server as claimed in claim 1, wherein the driving assembly further includes a sensing shaft for sensing a rotating angle of at least one gear, and the case further a second aperture for corresponding to the sensing shaft.
